(19) United States
(12) Patent Application Publication
(10) Pub. No.: US 2026/0093172 A1
(43) Pub. Date: Apr. 2, 2026

(54) SYSTEMS AND METHODS FOR PREDICTING POST-ETCH STOCHASTIC VARIATION

(71) Applicant: ASML NETHERLANDS B.V., Veldhoven (NL)

(72) Inventors: Chang An WANG, Poughkeepsie, NY (US); Yongfa FAN, Cupertino, CA (US); Mu FENG, San Jose, CA (US); Yi-Hsing PENG, Fremont, CA (US); Peigen CAO, San Jose, CA (US); Marleen KOOIMAN, Eindhoven (NL)

(73) Assignee: ASML NETHERLANDS B.V., Veldhoven (NL)

(21) Appl. No.: 18/859,379

(22) PCT Filed: Jun. 15, 2023
(86) PCT No.: PCT/EP2023/066192

§ 371 Date: Oct. 23, 2024

Related U.S. Application Data
(60) Provisional application No. 63/388,099, filed on Jul. 11, 2022.
(60) Provisional application No. 63/401,391, filed on Aug. 26, 2022.

(51) Int. Cl. G03F 1/36; G03F 1/42

(52) U.S. Cl. CPC G03F 1/36; G03F 1/42

(57) ABSTRACT

A method for predicting post-etch stochastic variation in transferring a target layout onto a substrate using a lithographic apparatus. The method includes predicting a stochastic variation in transferring a target layout onto a substrate by predicting a stochastic etch bias and combining the stochastic etch bias with post-lithographic process stochastic variation to predict the stochastic variation in an etch process. The method includes determining a performance in transferring the target layout to the substrate based on the stochastic variation.

### CROSS-REFERENCE TO RELATED APPLICATIONS

This application is the U.S. national phase entry of PCT Patent Application No. PCT/EP2023/066192, which was filed on Jun. 15, 2023, which claims priority of U.S. Provisional Patent Application No. 63/388,099 which was filed on Jul. 11, 2022, and of U.S. Provisional Patent Application No. 63/401,391 which was filed on Aug. 26, 2022, which are incorporated herein in their entireties by reference.

### TECHNICAL FIELD

The description herein relates to lithographic apparatuses and processes, and more particularly to optimization of a lithographic process for an improved process yield and throughput.

### BACKGROUND

A lithographic apparatus is a machine that applies a desired pattern onto a target portion of a substrate. The lithographic apparatus can be used, for example, in the manufacture of integrated circuits (ICs). For example, an IC chip in a smart phone, can be as small as a person's thumbnail, and may include over 2 billion transistors. Making an IC is a complex and time-consuming process, with circuit components in different layers and including hundreds of individual steps. Errors in even one step have the potential to result in problems with the final IC and can cause device failure. High process yield and high wafer throughput can be impacted by the presence of defects.

Metrology processes are used at various steps during a patterning process to monitor and/or control the process. For example, metrology processes are used to measure one or more characteristics of a substrate, such as a relative location (e.g., registration, overlay, alignment, etc.) or dimension (e.g., line width, critical dimension (CD), thickness, etc.) of features formed on the substrate during the patterning process or stochastic variation, such that, for example, the performance of the patterning process can be determined from the one or more characteristics. If the one or more characteristics are unacceptable (e.g., out of a predetermined range for the characteristic(s)), one or more variables of the patterning process may be designed or altered, e.g., based on the measurements of the one or more characteristics, such that substrates manufactured by the patterning process have an acceptable characteristic(s).

Some of the defects is caused by stochastic variations at both lithographic and etch steps such as local CD uniformity (LCDU), line edge roughness (LER), or local edge placement error (LEPE). In some embodiments, stochastics are events that have random variables. These variations, called stochastic effects, sometimes cause unwanted defects and pattern roughness in chips. Both can impact the performance of a chip or even cause a device to fail. The stochastic variations typically dominate edge placement error (EPE) budget at the advanced technology nodes. Stochastics induced defects have become a big part of yield pareto. In order to minimize the impact of stochastic variation and achieve high process yield, an integrated solution to measure stochastic variation, model stochastic variation and predict the stochastics induced defect at the full chip level may be preferred.

Among various stochastics induced defects, the interlayer stochastic defects have caught the industry's attention because they may be final and compounded effect of EPE between two subsequent layers such as metal and contact layers, or between two process steps such as lithography and etch. Such defects may have become primary source of the chip failure in the extreme ultraviolet (EUV) era. The industry is struggling to find a way to detect, characterize, and prevent such defects, and needs a solution to predict such defects at the full chip level before cutting a mask, exposing a wafer or etching a wafer. In order to deliver such a solution, not only post-lithographic stochastic modeling but also post-etch stochastic modeling solutions may be required.

### BRIEF SUMMARY

In some embodiments, there is provided a non-transitory computer readable medium having instructions that, when executed by a computer, cause the computer to execute a method for predicting post-etch stochastic variation in transferring a target layout onto a substrate using a lithographic apparatus. The method includes predicting a stochastic variation in transferring a target layout onto a substrate by executing a stochastic model configured to predict the stochastic variation in an etch process, wherein the stochastic model is configured to predict the stochastic variation based on stochastic etch bias and post-lithographic process stochastic variation; and determining a performance in transferring the target layout to the substrate based on the stochastic variation.

In some embodiments, there is provided a non-transitory computer readable medium having instructions that, when executed by a computer, cause the computer to execute a method for predicting post-etch stochastic variation in transferring a target layout to a substrate using a lithographic apparatus. The method includes: obtaining post-lithographic process stochastic variation associated with printing a target layout on a substrate using a lithographic process; predicting stochastic etch bias that is indicative of a stochastic variation in an etch process of etching a pattern corresponding to the target layout on the substrate, wherein the stochastic etch bias is determined as a function of at least one of concentration etch method, a density map, or a smooth factor; and obtaining the stochastic variation based on the stochastic etch bias and the post-lithographic process stochastic variation.

In some embodiments, there is provided a method for predicting post-etch stochastic variation in transferring a target layout onto a substrate using a lithographic apparatus. The method includes predicting a stochastic variation in transferring a target layout onto a substrate by executing a stochastic model configured to predict the stochastic variation in an etch process, wherein the stochastic model is configured to predict the stochastic variation based on stochastic etch bias and post-lithographic process stochastic variation; and determining a performance in transferring the target layout to the substrate based on the stochastic variation.

In some embodiments, there is provided an apparatus for predicting post-etch stochastic variation in transferring a target layout onto a substrate using a lithographic apparatus. The apparatus includes a memory storing a set of instructions and a processor configured to execute the set of instructions to cause the apparatus to perform a method of predicting a stochastic variation in transferring a target layout onto a substrate by executing a stochastic model configured to predict the stochastic variation in an etch process, wherein the stochastic model is configured to predict the stochastic variation based on stochastic etch bias and post-lithographic process stochastic variation; and determining a performance in transferring the target layout to the substrate based on the stochastic variation.

### BRIEF DESCRIPTION OF THE DRAWINGS

Embodiments will now be described, by way of example only, with reference to the accompanying drawings in which:

FIG. 1 is a block diagram of various subsystems of a lithography system, according to an embodiment.

FIG. 2 is a block diagram of simulation models corresponding to the subsystems in FIG. 1, according to an embodiment.

FIG. 3 is a block diagram of an exemplary system for predicting post-etch stochastic variation in transferring a target layout onto a substrate, consistent with various embodiments.

FIG. 4A shows a distribution of the post-etch contour, consistent with various embodiments.

FIG. 4B shows an image of post-etch contours predicted based on the post-etch stochastic variation, consistent with various embodiments.

FIG. 5 is a flow diagram of an exemplary method for predicting post-etch stochastic variation in transferring a target layout onto a substrate, consistent with various embodiments.

FIG. 6A shows an image of overlapping of contours of two layers of a portion of the target layout generated based on the post-etch stochastic variation predicted by a stochastic etch model, consistent with various embodiments.

FIG. 6B shows an enlarged view of a region where the contours of a first feature and a second feature are overlapped, consistent with various embodiments.

FIG. 6C shows a contour pair separated by a specified distance, consistent with various embodiments.

FIG. 7 is a block diagram of an exemplary system for predicting post-etch interlayer stochastic defects, consistent with various embodiments.

FIG. 8 is a flow diagram of an exemplary method for predicting post-etch interlayer stochastic defects, consistent with various embodiments.

FIG. 9 is a block diagram of an example computer system, according to an embodiment.

FIG. 10 is a flow diagram of another method for predicting post-etch stochastic variation in transferring a target layout onto a substrate, consistent with various embodiments.

FIG. 11 is an illustration of a resist contour and an etch contour, consistent with various embodiments.

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

### DETAILED DESCRIPTION

A lithographic apparatus is a machine that applies a desired pattern onto a target portion of a substrate. This process of transferring the desired pattern to the substrate is called a patterning process. The patterning process can include a patterning step to transfer a pattern from a patterning device (such as a mask) to the substrate. The mask is a master template for a given IC design. It is placed in a lithography apparatus, which projects light through the mask. That, in turn, is used to pattern images on a wafer (e.g., on a resist layer). Also, there can then be one or more related pattern processing steps, such as resist development by a development apparatus, baking of the substrate using a bake tool, etching the pattern onto the substrate using an etch apparatus, etc.

Various variations (e.g., variations in the patterning process or the lithographic apparatus) can potentially limit lithography implementation for semiconductor high volume manufacturing (HVM). For example, photon number or energy variations in an illumination source of the lithographic apparatus, focus or dose variations in projection optics of the lithographic apparatus, molecular size or photoacid diffusion variations in resist chemistry, plasma density distribution and pattern density variations in etch process etc. can lead to stochastic effects, such as pronounced line edge roughness (LER), edge placement errors (EPE), or local critical dimension (CD) variation in small two-dimensional features of the pattern. In some embodiments, the EPE (e.g., a distance between a point in a resist image to an intended position of that point in a target layout or design layout) dominates in error budget. Certain stochastic models may predict stochastic variations such as variations in CD or stochastic edge placement error (SEPE) based on predicted resist contours (e.g., contours of a pattern on resist after a substrate is exposed to the pattern using a lithographic process in a lithographic apparatus). Such predictions may be used in detecting defects and in optimizing various design variables (e.g., target CD, pupil shape associated with an illumination source, a mask bias, dose value, focus value, a mask type, mask bias, etch bias, etc.) for achieving a desired output from a lithographic process.

In some embodiments, the CD or EPE of a feature of the pattern may vary after an etch process, e.g., compared to before the etch process due to stochastic effects in the etch process. Such variations between two layers of the target layout may cause interlayer defects. That is, the interlayer stochastic defects may be a compounded effect of EPE between two subsequent layers such as metal and contact layers. Such defects have become primary source of the chip failure. Conventional techniques do not have a way to detect, characterize, predict, or prevent such post-etch interlayer or intra-layer stochastic defects at full-chip level.

Disclosed are embodiments for predicting stochastic variations after an etch process and identifying interlayer defects based on the post-etch stochastic variations. The embodiments may predict post-etch stochastic variation in transferring a target layout onto a substrate using a lithographic apparatus. The embodiments may include predicting the post-etch stochastic variation by predicting a stochastic etch bias and combining the stochastic etch bias with post-lithographic process stochastic variation. The embodiments may include determining a performance in transferring the target pattern to the substrate based on the stochastic variation.

The embodiments determine a stochastic etch bias (SEB), which may be a result of stochastic effects caused during the etch process. In some embodiments, the stochastic etch bias may be modeled as a function of several etch process related parameters, such as concentration etch method (CEM) parameters, pattern density map, or smooth factors. In some embodiments, stochastic etch bias indicates a difference between a stochastic variation after an etch process (σ_{SEPE-E}) and a stochastic variation after a lithographic process (σ_{SEPE-L}). The stochastic etch bias may be then combined with post-lithographic stochastic variation (σ_{SEPE-L}) to determine post-etch stochastic variation (σ_{SEPE-E}). In some embodiments, the post-etch stochastic variation is a variance value (σ²), which is indicative of a variation probability of a predicted contour due to the stochastic effects of the etch process. The post-etch stochastic variation (e.g., in the form of a stochastic variation band) may be characterized based on the variance and a position of a mean contour of a feature. The stochastic variation band of the variation probability may be representative of probable positions of a predicted contour relative to a mean contour or nominal contour after the etch process. For example, the stochastic variation band may indicate probable positions of the contour anywhere between ±3σ distance from the mean contour. Such post-etch stochastic variation predictions may be generated for various features of a target layout, or for all features of the target layout at a full-chip scale. The embodiments may also generate an image with post-etch contours predicted based on the post-etch stochastic variation. In some embodiments, the embodiments may generate multiple post-etch contours for a feature, each contour being at a different distance from the mean contour of the feature.

The post-etch stochastic variation may be determined for multiple layers of the target layout and interlayer defects may be determined by selecting two features of the target layout at a specified location in two different layers, overlapping the contours of the two features and determining a failure probability of a defect based on a distance between the contours. For example, if the distance between the two contours is less than a threshold distance, then a defect may be detected. In some embodiments, the failure probability is the cumulative probability of all combinations of the two post-etch contours with an inter-distance less than the threshold distance. By predicting the post-etch stochastic variations, various defects (e.g., interlayer or intra-layer defects) may be predicted and the patterning process may be optimized accordingly to prevent or minimize the defects and improve the manufacturing yield. For example, the patterning process may be optimized by adjusting illumination source parameters, projection optics parameters, mask parameters, resist parameters, or etch process parameters. Further, by predicting the post-etch stochastic variation, the embodiments are advantageous over conventional defect detection techniques that require actual inspection of printed wafers, which not only does not prevent or minimize the occurrence of defects since the wafer is already printed but also requires obtaining significant amount of metrology data, which is time consuming and resource intensive.

Disclosed are embodiments for determining a stochastic variation in an etch contour (referred to as “post-etch stochastic variation”) as a function of a sensitivity of an etch profile (e.g., the etch contour) to variations in a resist profile (e.g., a resist contour) (referred to as “post-lithographic stochastic variation”). In some embodiments, the sensitivity is a local sensitivity of the etch or resist profile. In some embodiments, the sensitivity may correspond to a derivative of etch profile to the resist profile. The sensitivity may be determined based on derivative of an etch model (e.g., a machine learning model, a physical or empirical etch model, a physical or empirical etch bias model, etc.) configured to predict an etch profile. The sensitivity may be determined as a function of several parameters that are typically used to either calibrate an etch bias model to determine the etch bias or calibrate a stochastic lithographic model to determine the post-lithographic stochastic variation model. For example, the etch bias may be modeled as a function of several etch process related parameters, such as CEM parameters, pattern density map, or smooth factors (referred to as “bias terms”), coefficients associated with the bias terms, and a constant, which is indicative of a variation induced by an etch process. The sensitivity may be determined as a function one or more of the coefficients, convolutions of the resist contour with a kernel (e.g., determined based on some of the bias terms) and a truncation of a convolution of the resist contour (e.g., determined based on some of the bias terms or terms used to calibrate the stochastic lithographic model), and correlation length of resist. After the sensitivity is determined, the post-etch stochastic variation may be determined based on a product of the sensitivity and post-lithographic stochastic variation, and the constant.

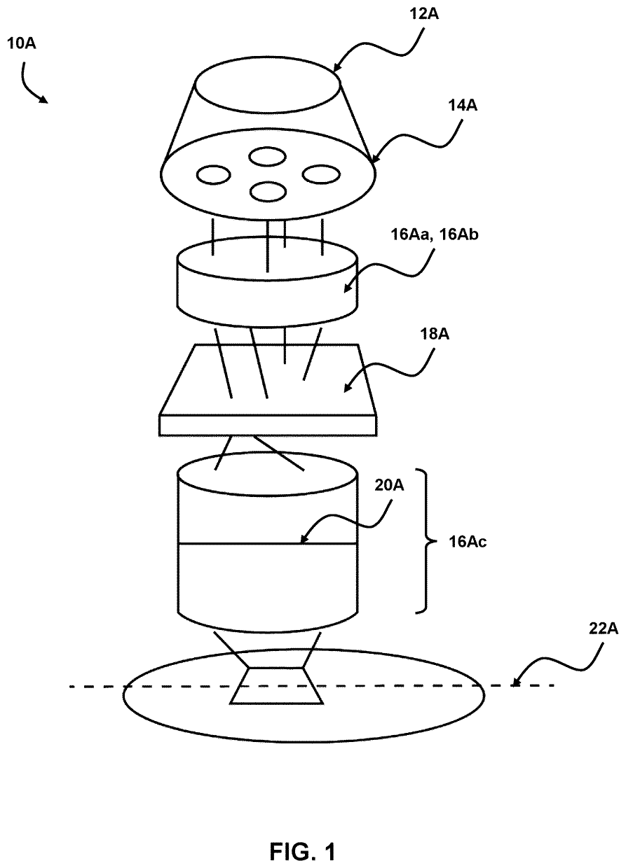

As a brief introduction, FIG. 1 illustrates an exemplary lithographic projection apparatus 10A.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range 5-20 nm).

The term “optimizing” and “optimization” as used herein mean adjusting a lithographic projection apparatus such that results or processes of lithography have more desirable characteristics, such as higher accuracy of projection of design layouts on a substrate, larger process windows, etc.

Further, the lithographic projection apparatus may be of a type having two or more substrate tables (or two or more patterning device tables). In such “multiple stage” devices the additional tables may be used in parallel, or preparatory steps may be carried out on one or more tables while one or more other tables are being used for exposures. Twin stage lithographic projection apparatuses are described, for example, in U.S. Pat. No. 5,969,441, incorporated herein by reference.

The patterning device referred to above comprises or can form design layouts. The design layouts can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. The design rule limitations are typically referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. More information on such mirror arrays can be gleaned, for example, from U.S. Pat. Nos. 5,296,891 and 5,523,193, which are incorporated herein by reference.
a programmable LCD array. An example of such a construction is given in U.S. Pat. No. 5,229,872, which is incorporated herein by reference.

Major components are a radiation source 12A, which may be a deep-ultraviolet excimer laser source or other type of source including an extreme ultra violet (EUV) source (as discussed above, the lithographic projection apparatus itself need not have the radiation source), illumination optics which define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=sin(Θₘₐₓ).

In an optimization process of a system, a figure of merit of the system can be represented as a cost function. The optimization process boils down to a process of finding a set of parameters (design variables) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics; the cost function can also be the maximum of these deviations (i.e., worst deviation). The term “evaluation points” herein should be interpreted broadly to include any characteristics of the system. The design variables of the system can be confined to finite ranges or be interdependent due to practicalities of implementations of the system. In case of a lithographic projection apparatus, the constraints are often associated with physical properties and characteristics of the hardware such as tunable ranges, or patterning device manufacturability design rules, and the evaluation points can include physical points on a resist image on a substrate, as well as non-physical characteristics such as dose and focus.

In a lithographic projection apparatus, a source provides illumination (i.e., light); projection optics direct and shapes the illumination via a patterning device and onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in commonly assigned U.S. Pat. No. 8,200,468, disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the source and the projection optics.

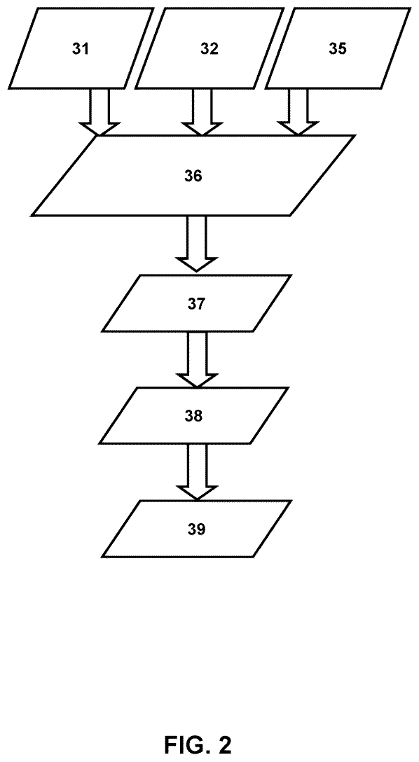

An exemplary flow chart for simulating lithography in a lithographic projection apparatus is illustrated in FIG. 2. As will be appreciated, the models may represent a different patterning process and need not comprise all the models described below. A source model 31 represents optical characteristics (including radiation intensity distribution or phase distribution) of the source. A projection optics model 32 represents optical characteristics (including changes to the radiation intensity distribution or the phase distribution caused by the projection optics) of the projection optics. A patterning device/design layout model 35 represents optical characteristics (including changes to the radiation intensity distribution or the phase distribution caused by a given design layout) of a design layout (e.g., a device design layout corresponding to a feature of an integrated circuit, a memory, an electronic device, etc.), which is the representation of an arrangement of features on or formed by a patterning device. An aerial image 36 can be simulated from the source model 31, the projection optics model 32 and the design layout model 35. A resist image 38 can be simulated from the aerial image 36 using a resist model 37. In some embodiments, the resist image 38 can be used an input to a post-pattern transfer process model 39. The post-pattern transfer process model 39 defines performance of one or more post-resist development processes (e.g., etch, development, etc.). For example, the post-pattern transfer process model 39 may be an etch model 39 that may be predict an etch image using the resist image 38. The etch image may be representative of contours etched on the substrate after the etch process. Simulation of lithography can, for example, predict contours and CDs in the resist image.

More specifically, it is noted that the source model 31 can represent the optical characteristics of the source that include, but are not limited to, numerical aperture settings, NA-sigma (a) settings as well as any particular illumination source shape (e.g. off-axis radiation sources such as annular, quadrupole, and dipole, etc.). The projection optics model 32 can represent the optical characteristics of the of the projection optics that include aberration, distortion, refractive indexes, physical sizes, physical dimensions, etc. The design layout model 35 can also represent physical properties of a physical patterning device, as described, for example, in U.S. Pat. No. 7,587,704, which is incorporated by reference in its entirety. The objective of the simulation is to accurately predict, for example, edge placements, aerial image intensity slopes and CDs, which can then be compared against an intended design. The intended design is generally defined as a pre-optical proximity correction (OPC) design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

In an example, computational analysis of the lithography or an etch process employs a prediction model (e.g., as discussed above with FIG. 2) that, when properly calibrated, can produce accurate prediction of dimensions from the lithography or the etch process. A model of lithography or etch processes is typically calibrated based on empirical measurements. This calibration may include running a test wafer with different process parameters, measuring resulting critical dimensions after lithography process, and calibrating a model to fit the measured results. In practice, fast and accurate models serve to improve device performance or yield, enhance process windows or increase design choices. It can be understood by a person skilled in the art that the methods described herein are not limited to a particular model of the lithography. For calibration of a desired model, images can be obtained after any semiconductor fabrication steps. For example, an aerial image, a resist image, an etch image, an image after a chemical mechanical polishing, or other images related to a process of the patterning process.

In computational lithography models, usually CD gauges measured by CD-SEM (Scanning Electron Microscope) are used as input data to calibrate the model. A goal of lithography modelling is to predict accurate resist contours for every location on the substrate. Similarly, a goal of etch modelling is to predict accurate etch contours for every location on the substrate. In some embodiments, computational analysis of an etch process employs a calibrated prediction model that can predict dimensions of etched structures resulting from the etch process. For example, an etch model related to the etch process may be calibrated based on empirical measurements. The calibration process may include patterning a test wafer with different process parameters, measuring CDs of a pattern on the test wafer after the etch process, and calibrating the etch model based on the measured CDs. In practice, a fast and accurate model can be employed to improve a performance of a patterning apparatus, a patterning yield, process windows of the patterning process, or increase design choices related to e.g., determining mask patterns.

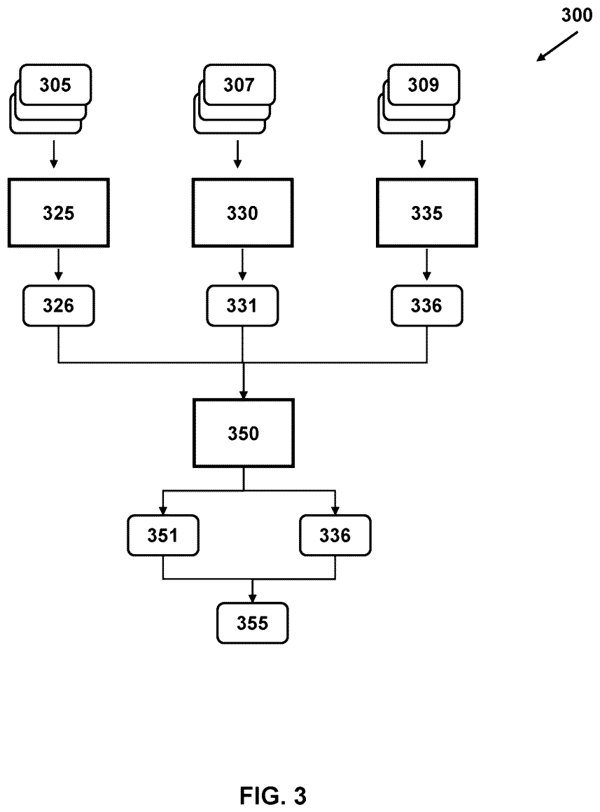

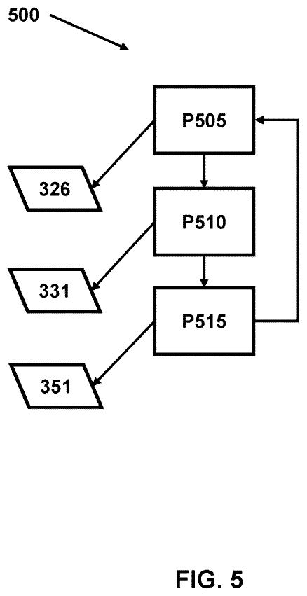

The following paragraphs describe a system and a method to predict post-etch stochastic variation in transferring a target layout onto a substrate using a lithographic apparatus such as the apparatus of FIG. 1. FIG. 3 is a block diagram of an exemplary system 300 for predicting post-etch stochastic variation in transferring a target layout onto a substrate, consistent with various embodiments. FIG. 5 is a flow diagram of an exemplary method 500 for predicting post-etch stochastic variation in transferring a target layout onto a substrate, consistent with various embodiments.

At process P505, a stochastic lithographic model 325 obtains post-lithographic stochastic variation 326 (e.g., σ_{SEPE-L}). The post-lithographic stochastic variation 326 is indicative of a variance of a contour of a feature of a target layout in a resist layer of the substrate (e.g., variance from a mean contour predicted by a resist model) after a lithographic process of printing the target layout is completed. In some embodiments, the variation may be due to stochastic effects in printing the target layout. In some embodiments, the post-lithographic stochastic variation 326 (σ_{SEPE-L}) may be measured in terms of σ-sigma (e.g., standard deviation), or variance (σ²) from which a may be obtained. The stochastic lithographic model 325 may determine, based on the variance, a post-litho stochastic variation band, which is representative of probabilities of positions of a resist contour (e.g., contour of a feature of the target layout in a resist of the substrate) from a mean contour or nominal contour after the lithographic process. For example, the post-litho stochastic variation band may indicate a variation probability of the contour being at a distance between ±3σ from the mean contour. The position or location of the mean contour on the resist may be determined based on the EPE of the mean contour (e.g., distance between the mean contour and the corresponding contour in the target layout), which may be obtained from simulations of a lithographic process (e.g., simulation process of FIG. 2).

The post-lithographic stochastic variation 326 may be a result of the stochastic effects. In some embodiments, these stochastic effects may be modeled or simulated using various parameters 305 associated with the lithographic process or the lithographic apparatus. For example, some of the parameters may include optical sensitivity parameters 305 such as image log slope (ILS), optical image slope or contrast (e.g., optical lmax and lmin). In another example, the parameters 305 may include photon and photoacid kinetics parameters such as PK and PKI which are representative of the photon 2D and 3D distribution on a substrate, respectively. In another example, the parameters 305 may include resist chemistry parameters.

In some embodiments, the stochastic lithographic model 325 may be implemented as a predictive model to predict the post-lithographic stochastic variation 326. The stochastic lithographic model 325 may be configured (e.g., calibrated with empirical data) to predict post-lithographic stochastic variation 326. For example, the calibration process may include patterning a test substrate with different process parameters, measuring stochastic variation of CDs or EPEs of a pattern on the test substrate after the lithographic process, and calibrating the stochastic lithographic model to fit the measured CDs or EPEs and values of parameters 305. Once calibrated, the stochastic lithographic model 325 may be used to predict the post-lithographic stochastic variation 326 (σ_{SEPE-L}) for any location or feature in a given target layout for a given set of parameters 305. One example implementation of calibrating and deploying the calibrated model to predict the post-lithographic stochastic variation 326 is described below.

As described above, the post-lithographic stochastic variation 326 may be determined as a function of various parameters 305. That is, the stochastic lithographic model 325 may be represented as:

$${σ}_{sepe - 1} = f ( ILS , Slope , CTMX , CTMN , PK , PKI , AP , Bp , Am , Bn ) \qquad Eq . ( l )$$

where σₛₑₚₑ₋₁ is post-lithographic stochastic variation 326, parameters 305 such as PK (Photon kinetics) is photon 2D distribution on a substrate; PKI is photon 3D distribution on a substrate; ILS is optical image log-slope; Slope is optical image slope; CTMX and CTMN are derived from optical lmax or lmin of image envelope; Ap/Bp/Am/Bn are various resist truncation terms for base/acid reaction; and a₁-aₙ, b, x and y are coefficients.

The stochastic lithographic model 325 can be calibrated using empirical data obtained from inspecting a test substrate on which a pattern is printed. For example, σₛₑₚₑ₋₁, and CD may be obtained from metrology data associated with the test substrate (e.g., obtained by inspecting SEM images of the test substrate), and values of image parameters 305 may be determined using an optical proximity correction (OPC) model, which is used to optimize design layouts or patterning devices. Such empirical data may be obtained for various such substrates. Both empirical data and OPC model may be input to the stochastic lithographic model 325, which determines the values of the coefficients a₁-aₙ, b, x and y (e.g., using a linear solver). After the coefficients are determined, the stochastic lithographic model 325 may be considered as calibrated.

The calibrated stochastic lithographic model 325 may be used in determining (e.g., predicting) the post-lithographic stochastic variation 326 in printing any target layout/design layout on any substrate. For example, the values of parameters 305 for a sampling location on a given design layout/target layout may be determined using a simulation engine (e.g., based on the CD values) that is configured to predict the values of the image parameters 305. The parameter values are then input to the stochastic lithographic model 325, which may determine the post-lithographic stochastic variation 326 (σₛₑₚₑ₋₁) based on the parameter values and the coefficients.

Referring to FIG. 5, at process P510, a stochastic etch bias model 330 obtains (e.g., predicts) stochastic etch bias 331 (e.g., SEB). In some embodiments, the stochastic etch bias 331 is indicative of a difference between a stochastic variation after an etch process (σ_{SEPE-E}) and the stochastic variation after a lithographic process (σ_{SEPE-L}). The stochastic etch bias may be a value that may be combined with post-litho stochastic variation of a contour of a feature (e.g., feature contour on the substrate after lithographic process) to obtain a post-etch stochastic variation, and after-etch contour of the feature (e.g., feature contour on the substrate after the etch process).

The stochastic etch bias model 330 may be implemented as a predictive model that is configured to predict the stochastic etch bias based on parameters that may be used to model the stochastic effects during the etch process. In some embodiments, the stochastic etch bias may be defined as a function of plasma etch process related parameters such as plasma concentration-based method's CEM terms C_{R} (resist area) and C_{T} (trench area) which describe material-plasma interaction effect on contour/CD evolution during etch process, a pattern density map of sublayer (PM), or other smoothing factors which are determined by optical sensitivity or design geometry or resist chemistry. For example, CEM parameters may be a function of etch rate, etch profile, reaction time, C_{T} and C_{R} that describe the material-plasma interaction, etc. The pattern density map is defined as a function of the two-dimensional distribution of design pattern features across a mask. In some embodiments, smooth factors (Sm) defined to describe optical sensitivity or design geometry or resist chemistry related parameters such as ILS, Slope, Contrast, PK terms and resist truncation terms Ap/Bp/Am/Bn.

The stochastic etch bias model 330 may be represented as:

$$SEB = f ( CEM , Pattern density map , Smooth factors ) \qquad Eq . ( 2 )$$

The present disclosure is not limited to any specific mathematical form of the SEB. The factors can be combined mathematically in any suitable manner, e.g., based on theories or empirically. In some embodiments, the function of Eq. 2 may be expressed using a linear equation, polynomial form or log form or exponential form. For example, each factors of the equation may be associated with a calibration parameter.

The stochastic etch bias model 330 may be calibrated. In some embodiments, the stochastic etch bias model 330 may be calibrated using empirical data obtained from inspecting a test substrate on which a pattern is transferred, or simulated process parameters from design geometry and OPC model, or a combination thereof. For example, σₛₑₚₑ₋₁, and σₛₑₚₑ₋ₑ may be obtained from metrology data associated with the test substrate (e.g., obtained by inspecting SEM images of the test substrate) after lithography and etch processes, respectively, and the stochastic etch bias may be determined as difference between σₛₑₚₑ₋ₑ and σₛₑₚₑ₋₁. Further, the values of the parameters 307 such as Ct, Cr, PM, or Sm may be simulated using an OPC model or other models. Such empirical data may be obtained for various substrates. The empirical data and simulated parameters may be input to the stochastic etch bias model 330, which determines the values of the coefficients. After the coefficients are determined, the stochastic etch bias model 330 may be considered as calibrated.

The calibrated stochastic etch bias model 330 may be used in predicting the stochastic etch bias for any sampling location in the design layout. For example, values of the parameters 307 such as Ct, Cr, PM, or Sm may be obtained using a simulation engine that is configured to predict the parameter values for any sampling location on a design layout/target layout. The values of parameter 307 may be input to the stochastic etch bias model 330, which determines the stochastic etch bias 331 based on the parameter values and the coefficients.

Referring to method 500, at process P515, a stochastic etch model 350 may predict the post-etch stochastic variation 351 based on the post-lithographic stochastic variation 326 and stochastic etch bias 331 (e.g., obtained in process P505 and P510, respectively). For example, the stochastic etch model 350 may determine the post-etch stochastic variation 351 as a combination of the post-lithographic stochastic variation 326 and stochastic etch bias 331. For example, the post-etch stochastic variation 351 may be represented as:

$${σ}_{sepe - e} = {σ}_{sepe - 1} + SEB \qquad Eq . ( 3 )$$

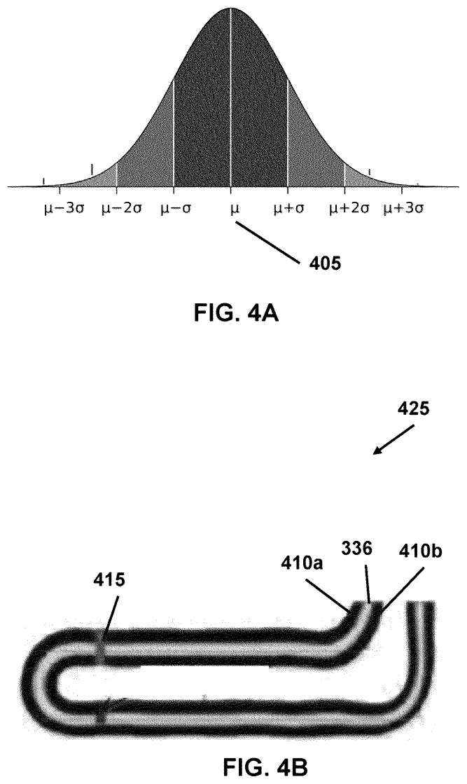

As described above, the post-etch stochastic variation 351 is calculated as variance, which is indicative of a variation of a predicted post-etch contour due to the stochastic effects of the etch process. The post-etch stochastic variation 351 (e.g., represented in a form of stochastic variation band) may be characterized based on the variance respect to the post etch contour simulated by the etch model 39 and a position of a mean post etch contour of a feature. The stochastic variation band may be representative of probable positions of a predicted post-etch contour relative to a mean contour. In some embodiments, the stochastic variation band may be simulated as a Gaussian distribution of a predicted post-etch contour around a position of the mean contour. FIG. 4A shows a distribution of the post-etch contour, consistent with various embodiments. The position 405 (or location) of the mean contour, p, on the substrate may be determined based on the EPE of the mean contour (e.g., distance between the mean contour and the corresponding contour in the target layout), which may be obtained from simulations of a patterning process. After the position 405 of the mean contour is determined, the post-etch stochastic variation band may be determined as a Gaussian distribution using the σ value (e.g., σₛₑₚₑ₋ₑ) obtained from Equation 5. For example, the post-etch stochastic variation band may indicate a variation probability of the post-etch contour within ±3σ distance from the position 405 of the mean contour.

In some embodiments, the stochastic etch model 350 may then generate an image (e.g., after etch image (AEI)) of post-etch contours predicted based on the post-etch stochastic variation band. For example, the stochastic etch model 350 may generate a first image 425 of post-etch contours 410a and 410b of a feature as shown in FIG. 4B. FIG. 4B shows a first image 425 of post-etch contours predicted based on the post-etch stochastic variation, consistent with various embodiments. The stochastic etch model 350 predicts a stochastic variation band 415, which is a range of the stochastic variation within which the etch contour of a feature may occur after the etch process. For example, the stochastic etch model 350 may generate a first etch contour 410a (e.g., outer contour) of the feature at a first sigma value from a mean contour 336 and a second etch contour 410b (e.g., inner contour) of the feature at a second sigma value from the mean contour 336.

In some embodiments, the mean contour 336 may be generated using an etch model 335. As described above, etch modelling may be used to predict etch contours across the substrate. In some embodiments, the etch model 335 may be used in obtaining or predicting the post-etch contour for a feature in the design layout. For example, parameters 309 such as a resist image having resist contours for the given target layout may be obtained using a resist model (e.g., as described at least with reference to FIG. 2) and input to the etch model 335, which simulates, predicts or generates a post-etch contour based on the resist image. For example, the etch model 335 generates an image (e.g., AEI) having the nominal contour 336 of the feature.

Thus, the stochastic etch model 350 can predict or generate a second image 355 (e.g., AEI) having post-etch contours determined based on the post-etch stochastic variation 351. In some embodiments, the second image 355 or at least a portion of the second image 355 may be similar to the first image 425 of FIG. 4B.

While the foregoing paragraphs describe the stochastic etch model 350 predicting the post-etch stochastic variation 351 based on post-lithographic stochastic variation 326 and the stochastic etch bias 331, the stochastic etch model 350 may consider other processes in predicting the post-etch stochastic variation 351. For example, the stochastic etch model 350 may also incorporate litho manufacturability check (LMC), which is a procedure followed by OPC or source mask optimization (SMO) process to verify if the mask generated based on determined mask pattern satisfies the manufacturability requirement (e.g., which may involve simulating a lithographic process as described at least with reference to FIG. 2). If the LMC procedure fails, one or more design variables in the SMO or OPC process may be adjusted, and the method 500 may be executed again to determine post-etch stochastic variation 351. In some embodiments, a design variable may include one or more of a target CD of the target layout, a mask bias, a mask type (e.g., binary mask, optical mask, EUV mask, etc.), a pupil of an illumination source of the lithographic apparatus, a dose of the illumination source, or a focus associated with radiation from the illumination source, or any other suitable variables that can be optimized in an OPC or SMO process, an etch bias, etc.

Stochastics induced defects could occur intralayer (within layer such as metal or gate layer) or interlayer (between two adjacent layers). Intralayer defects can be predicted by using single layer stochastic model at either post-litho or post-etch, but the prediction of the interlayer defects may be done using stochastic models from both layers, (e.g., stochastic etch model 350 for both layers).

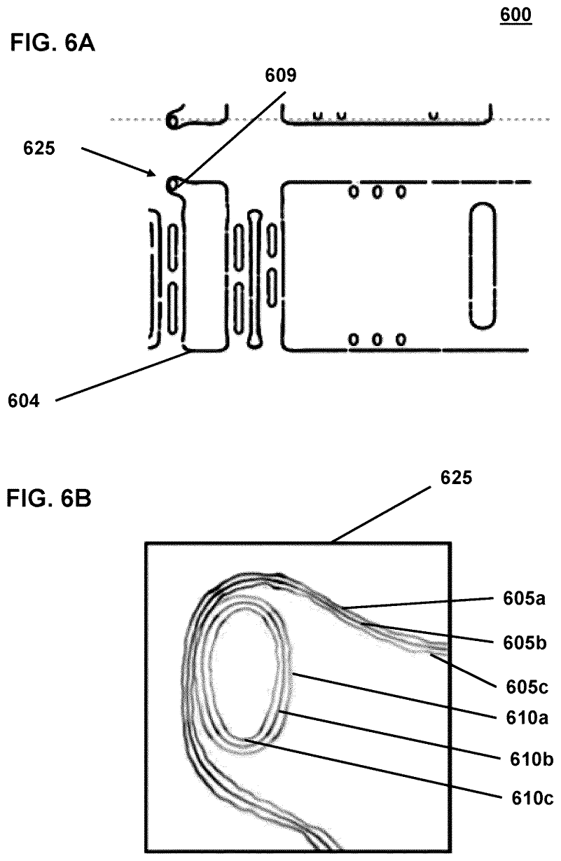

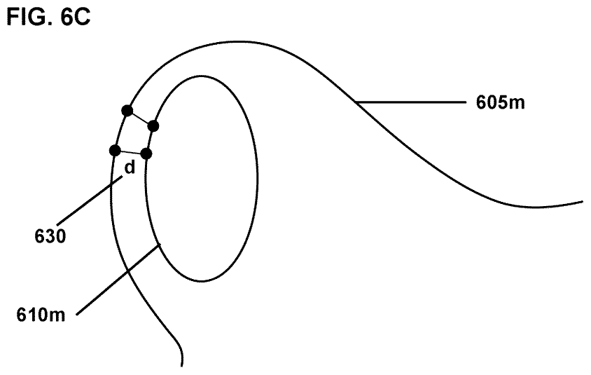

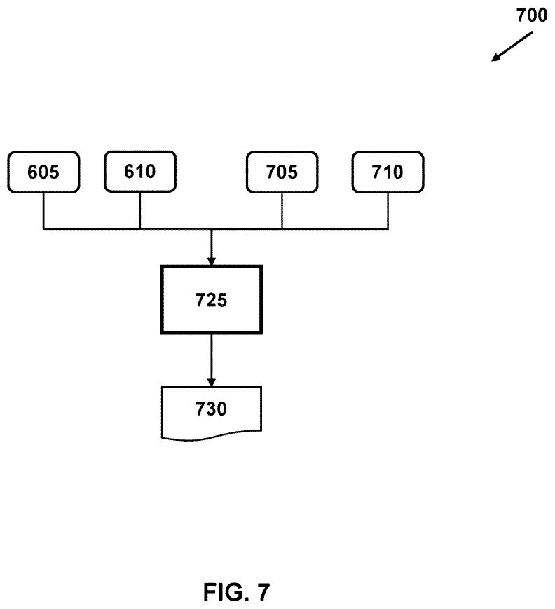

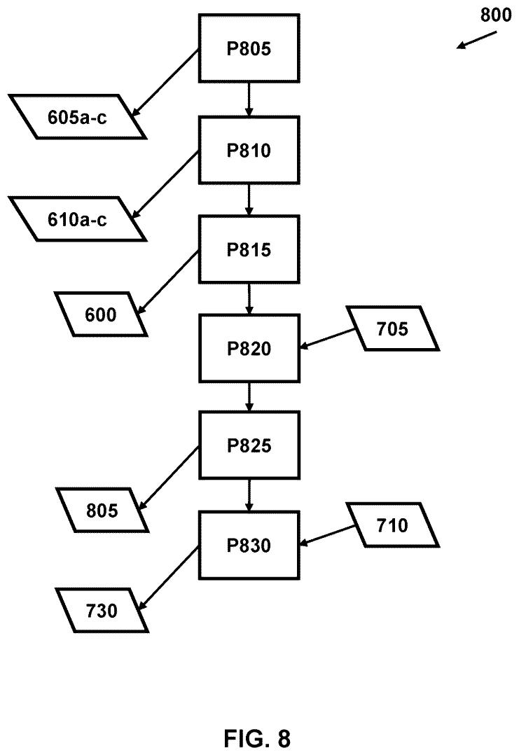

The following paragraphs describe an exemplary method to predict post-etch interlayer stochastic defects at a full chip level according to embodiments of the present disclosure. FIGS. 6A-6C illustrate post-etch contours of one or more layers of a design layout predicted based on post-etch stochastic variation, consistent with various embodiments. FIG. 7 is a block diagram of an exemplary system 700 for predicting post-etch interlayer stochastic defects, consistent with various embodiments. FIG. 8 is a flow diagram of an exemplary method 800 for predicting post-etch interlayer stochastic defects, consistent with various embodiments.

In some embodiments, the method 500 of determining post-etch stochastic variation 351 is executed at a full chip level to determine the post-etch stochastic variation 351 for all features of the target layout (e.g., for all features in multiple layers of the target layouts). FIG. 6A shows an image 600 of overlapping contours of two layers of a portion of the target layout generated based on the post-etch stochastic variation 351 predicted by a stochastic etch model, consistent with various embodiments. The image 600 shows one or more contours of a set of features in a first layer (A) of the target layout overlapped with one or more contours of a set of features in a second layer (B) of the target layout in which the first and second layers are consecutive layers of the target layout. For example, multiple contours of a first feature 604 in the first layer are overlapped with multiple contours of a second feature 609 in the second layer. FIG. 6B shows an enlarged view of a region 625 where the contours of the first feature 604 and the second feature 609 are overlapped, consistent with various embodiments. The three contours 605a-605c of the first feature 604 are overlapped with the three contours 610a-610c of the second feature 609. In some embodiments, a first contour 605a (e.g., outer contour) of the first feature 604 is generated at +1σ distance from a mean contour 605b and a second contour 605c (e.g., inner contour) of the first feature 604 is generated at −1σ distance from the mean contour 605b. Similarly, a first contour 610a (e.g., outer contour) of the second feature 609 is generated at +1σ distance from a mean contour 610b and a second contour 610c (e.g., inner contour) of the second feature 609 is generated at −1σ distance from the mean contour 610b. While the foregoing paragraph describes determining post-etch interlayer stochastic defects between two layers, the post-etch interlayer stochastic defects may be determined for more than two layers of the target layout.

At process P805, post-etch contours of a first feature in a first layer of a target layout are obtained. For example, a defect prediction model 725 may obtain contours 605a-605c of the first feature 604 in the first layer of the target layout using a stochastic etch model as described above. The stochastic etch model may determine a stochastic variation band for a contour of the first feature 604 and generate one or more contours 605a-605c based on the stochastic variation band of the first feature 604, e.g., as described at least with reference to FIGS. 4A-4B and 5.

At process P810, post-etch contours of a second feature in a second layer of a target layout are obtained. For example, the defect prediction model 725 may obtain contours 610a-610c of the second feature 609 in the second layer of the target layout using a stochastic etch model. The stochastic etch model may determine a stochastic variation band for the contours of the second feature 609 and generate one or more contours 610a and 610c based on the stochastic variation band of the second feature 609, e.g., as described at least with reference to FIGS. 4A-4B and 5.

In some embodiments, different stochastic etch models may be used to simulate the post-etch contours for different layers of the target layout. For example, a first stochastic etch model may be calibrated to obtain the post-etch stochastic variation (and simulate the post-etch contours) for features in a first layer of the target layout and a second stochastic etch model may be calibrated to obtain the post-etch stochastic variation (and simulate the post-etch contours) for features in a second layer of the target layout.

At process P815, an image with contours of the first feature and the second feature overlapped may be generated. For example, the contours 605 (e.g., 605a-605c) of the first feature 604 and the contours 610 (e.g., 610a-610c) of the second feature 609 may be provided as input to the defect prediction model 725, which generates an image 600 of FIG. 6A having contours of the features from different layers overlapped.

At process P820, a threshold distance 705 for determining a defect is received. In some embodiments, the threshold distance 705 may be the minimum distance that needs to be present between contours of two features below which they may be considered to be failure contours. The defect prediction model 725 may obtain the threshold distance 705 in various ways. For example, a user may input the threshold distance to the defect prediction model 725.

At process P825, a failure probability 805, which is a cumulative probability of all combinations of the two post-etch contours of the two features with an inter-distance less than the threshold distance 705, is determined. For example, the defect prediction model 725 may determine a probability that a contour distance 630, d, which is a distance between a contour pair 605m and 610m (e.g., as illustrated in FIG. 6C), is less than the threshold distance 705. In some embodiments, a contour pair includes a first post-etch contour of a first feature and a second post-etch contour of a second feature. The contour 605m can be any one of the contours 605a-605c or any contour in the Gaussian distribution associated with the first feature 604, and the contour 610m can be any one of the contours 610a-610c or any contour in the Gaussian distribution associated with the second feature 609. The defect prediction model 725 may determine such a failure probability for any and all combinations of the contour pairs of the features 604 and 609 in a cumulative way (e.g., using a cumulative distribution function).

At process P830, a defect may be detected based on the failure probability satisfying a threshold probability 710. For example, the defect prediction model 725 may determine a presence of an interlayer defect if the failure probability 805 is equal to or exceeds the threshold probability 710. The defect prediction model 725 may obtain the threshold probability 710 in various ways, e.g., via a user input. In some embodiments, the defect prediction model 725 may perform the above process for some or all features in the two layers, or various other layers in the design layout at a full chip scale, and determine the interlayer defects and their locations and output a performance report 730. The performance report 730 may include information regarding various defects detected and their locations in the substrate or the design layout. In some embodiments, the performance report 730 is indicative of a performance of (a) the lithographic process used to print the target layout on the substrate, or (b) an etch process used to transfer the target layout to the substrate. The performance report 730 may be used as a guidance for various optimization processes to optimize one or more design variables of a patterning process to transfer the target layout onto the substrate. In some embodiments, a design variable may include one or more of a target CD of the target layout, a mask bias, a mask type (e.g., binary mask, optical mask, EUV mask, etc.), a pupil of an illumination source of the lithographic apparatus, a dose of the illumination source, or a focus associated with radiation from the illumination source, an etch bias, or any other suitable variables that can be optimized in an OPC or SMO process, etc.

While the foregoing description of FIG. 8 describes detection of interlayer defects, the method 800 may also be implemented for determining intra-layer defects. For example, like a defect is determined by comparing two features 604 and 609 in two different layers and determining the failure probability 805 as described above, an intra-layer defect may be determined by comparing two features within the same layer of the design layout and determining a failure probability. If the failure probability is equal to or greater than the threshold probability, an intra-layer defect may be detected.

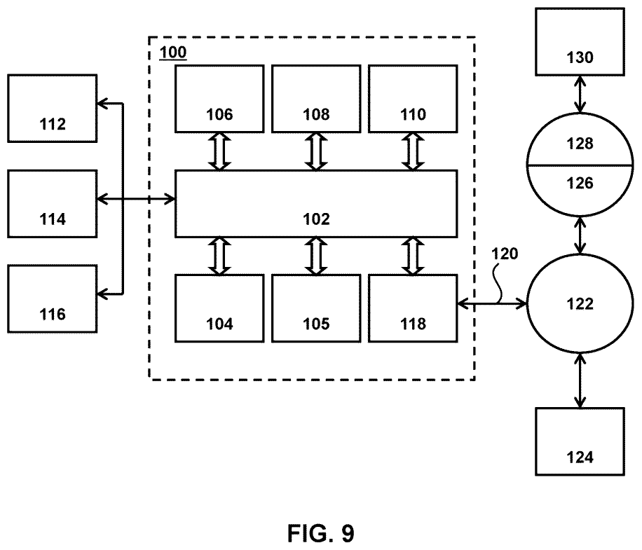

FIG. 9 is a block diagram that illustrates a computer system 100 which can assist in implementing in various methods and systems disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also preferably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, or stored in storage device 110, or other non-volatile storage for later execution. In this manner, computer system 100 may obtain application code in the form of a carrier wave.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

The descriptions herein are intended to be illustrative, not limiting. Thus, it will be apparent to one skilled in the art that modifications may be made as described without departing from the scope of the claims set out below.

The following paragraphs describe determining a stochastic variation in an etch profile (e.g., etch contour) (referred to as “post-etch stochastic variation”) as a function of a sensitivity of the etch profile (e.g., the etch contour) to variations in a resist profile (e.g., resist contour) (referred to as “post-lithographic stochastic variation”). In some embodiments, the sensitivity indicates a local sensitivity of the etch or resist profile. In some embodiments, the sensitivity may correspond to a derivative of etch profile to the resist profile, where the resist profile can be predicted based on one or more lithography models as described above, or can be obtained by metrology or inspection on a wafer. In some embodiments, the sensitivity may be determined based on derivative of an etch model (e.g., a machine learning model, a physical or empirical etch model, a physical or empirical etch bias model, etc.) configured to predict an etch profile.

In some embodiments, the sensitivity can be obtained based on an etch bias model (e.g., traditional etch bias model) and post-lithographic stochastic variation (e.g., determined using stochastic lithographic model 325). In some embodiments, a post-lithographic stochastic variation indicates a variation of a feature contour in a resist (e.g., “resist contour”) on the substrate after a lithographic process, and post-etch stochastic variation indicates a variation probability of a feature contour after an etch process (e.g., “etch contour”). In this example, the sensitivity of the etch bias model indicates the sensitivity of the etch contour to a stochastic variation in a resist contour. For example, the post-etch stochastic variation may be represented as:

$${σ}_{SEPE - E} ( \vec{r} ) = \sqrt{{( γ ( \vec{r} ) {σ}_{SEPE - L} ( \vec{r} ) )}^{2} + {b}^{2}} \qquad Eq . ( 4 )$$

Where \vec{r} is the location along a contour, σ_{SEPE-L}(\vec{r}) is the measured or predicted post-lithographic stochastic variation, b is a constant that denotes the etch-induced roughness, and function y(\vec{r}) is the sensitivity of the etch bias model and is the etch reduction factor.

For example, if y(\vec{r}) is less than “1,” the post-etch stochastic variation is reduced after the etch process. In case y(\vec{r}) is larger than “1,” the post-etch stochastic variation is amplified after the etch process. y(\vec{r}) may be derived in terms of the calibrated etch bias model for transferring a mean contour by the etch process. For example, the etch bias model may determine the etch bias as a function of several etch process related parameters, such as CEM parameters, pattern density map, or smooth factors (referred to as “bias terms”), coefficients associated with the bias terms, and a constant, which is indicative of a variation induced by an etch process. The etch bias may be represented as:

$$SEB = {\sum }_{i} {c}_{i} \cdot {term}_{{bias}_{i}} + {Constant}_{bias} \qquad Eq . ( 5 )$$

Where term_{bias}_{ᵢ} are i^{th} bias term, cᵢ is the coefficient of the i^{th} bias term, Constant_{bias} is a constant, which is indicative of an etch-induced bias to the mean resist contour.

In some embodiments, the sensitivity of the etch bias model corresponds to the sensitivity of the etch contour to variations in a resist contour. For example, the sensitivity may be determined as a function of several parameters that are typically used to either calibrate the etch bias model or the stochastic lithographic model. Accordingly, based on Equations (4) and (5), the post-etch stochastic variation may be expressed as:

$${( γ ( \vec{r} ) {σ}_{SEPE - L} ( \vec{r} ) )}^{2} = {σ}_{SEPE - L} ( \vec{r} ) {( 1 + 2 Γ ( 1 + \frac{1}{2 α} ) ξ {\sum }_{i} {c}_{i} \cdot {θ}_{i} ( \vec{r} ) {K}_{i} ( 0 ) )}^{2} \qquad Eq . ( 6 )$$

Accordingly, the sensitivity may be represented as:

$$γ ( \vec{r} ) = 1 + 2 Γ ( 1 + \frac{1}{2 α} ) ξ {\sum }_{i} {c}_{i} \cdot {θ}_{i} ( \vec{r} ) {K}_{i} ( 0 ) \qquad Eq . ( 7 )$$

Where Γ is the Euler gamma function, ξ is the correlation length of the resist, a is the exponent in the stretched exponential form, Kᵢ is convolutions of the resist contour with a kernel (e.g., determined based on some of the bias terms such as CEM parameters, pattern density map, or smooth factors), and θᵢ is truncation of a convolution of the resist contour (e.g., determined based on some of the resist truncation bias terms such as Ap/Bp/Am/Bn).

That is, the sensitivity may be determined as a function one or more of the coefficients, convolutions of the resist contour with a kernel and a truncation of a convolution of the resist contour, and correlation length of resist. After the sensitivity is determined, the post-etch stochastic variation for transferring any target layout to a substrate based on the constant and a product of the sensitivity and measured or predicted post-lithographic stochastic variations, for example as illustrated in Equation (4).

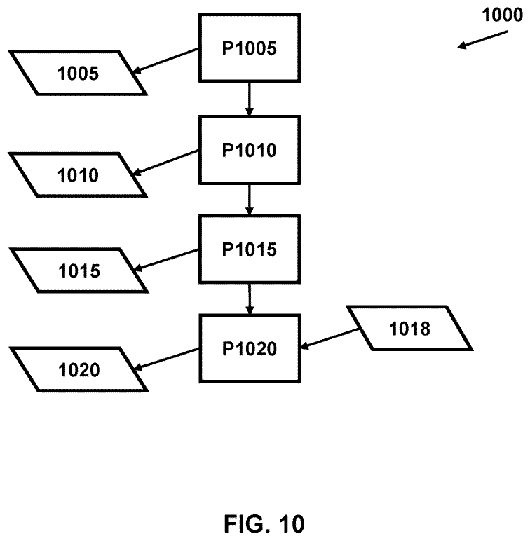

FIG. 10 is a flow diagram of another method 1000 for predicting post-etch stochastic variation in transferring a target layout onto a substrate, consistent with various embodiments.

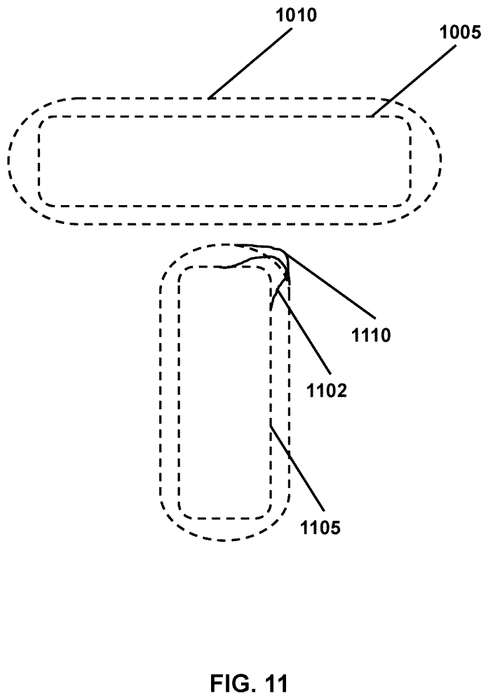

At process P1005 a resist contour 1005 of a feature in a target layout is obtained. The resist contour 1005 may be obtained in various ways. For example, a resist contour may be obtained by executing a resist model (e.g., the resist model 37 of FIG. 2), that is configured to predict the resist contour 1005 of the feature from an aerial image as described at least with reference to FIG. 2. The resist contour may also be obtained through wafer measurement. In some embodiments, the resist contour 1005 is a mean resist contour. The target layout may include multiple features and the resist contour may be obtained for one or more the features. FIG. 11 illustrates an example resist contour 1005.

At process P1010, an etch contour 1010 is obtained from the resist contour 1005. The etch contour 1010 may be obtained in a number of ways. For example, the etch contour 1010 may be obtained by executing an etch model (e.g., etch model 39 of FIG. 2 or etch model 335 of FIG. 3) which generates an etch contour from a resist contour. As described above, etch modelling may be used to predict etch contours across the substrate. For example, parameters such as a resist image having resist contours for the given target layout may be obtained using a resist model (e.g., as described at least with reference to process P1005) and input to the etch model, which simulates, predicts or generates an etch contour based on the resist image. For example, the etch model generates an etch contour 1010 as illustrated in FIG. 11. In some embodiments, the etch contour 1010 is a mean etch contour.

At process P1015, a sensitivity 1015 of the etch contour 1010 to a variation in the resist contour 1005 is determined. In some embodiments, the sensitivity of the etch contour 1010 may be determined based on a calibrated etch bias model. For example, a variation 1102 may be added to the resist contour 1005 to generate a modified resist contour 1105. Further, an updated etch contour 1110 may be obtained from the modified resist contour 1105 using the etch model. The sensitivity 1015 may then be computed based on the updated etch contour 1110, the modified resist contour 1105 using the calibrated etch bias model. In some embodiments, the sensitivity may be determined as a function one or more of the coefficients of the etch bias model, convolutions of the resist contour with a kernel and a truncation of a convolution of the resist contour, and correlation length of resist. For example, the sensitivity 1015 may be determined using the Equation (7) above.

At process P1020, a post-etch stochastic variation 1020 may be determined for any target layout based on the sensitivity 1015. For example, the user may input the target layout and a measured or predicted post-lithographic stochastic variation 1018, and a stochastic etch model 350 may determine the post-etch stochastic variation 1020 based on the sensitivity 1015 (e.g., using the Equation (4)).

While the foregoing description is related to determining the sensitivity of the etch contour to a variation in the resist contour based on an etch bias model, other models may be used to determine the sensitivity. For example, a machine learning (ML) model that is trained to generate an etch contour from a resist contour may be used to determine the sensitivity. In some embodiments, a resist model, such as the resist model 37, may be a ML model that is trained to generate a resist image from an aerial image. A profile of a feature (e.g., resist contour, or resist image) may be extracted from the resist image. Similarly, an etch model, such as the etch model 39, may be a ML model that is trained to generate an etch image using a resist image. A profile of a feature (e.g., etch contour or etch image) may be extracted from the etch image.

The following paragraphs describe determining the sensitivity using a model, M, for example, etch model or the etch bias model. For example, a resist profile (e.g., resist contour 1005) is input to an etch model (e.g., a ML model) to generate an etch profile (e.g., etch contour 1010). In some embodiments, the resist contour is a mean resist contour. The etch contour may be represented as a function of the model, M, used to generate the etch contour 1010 as below:

$$EC ( \vec{r} ′ ) = M [ RC ( \vec{r} ) ] \qquad Eq . ( 8 )$$

Where EC is the etch contour and RC is the resist contour.

The sensitivity of the model, M, may be determined as a derivative of the etch contour with respect to the resist contour. In some embodiments, to determine the derivative, the model may be evaluated by adding a perturbation 1102 on a mean resist contour at a certain point r and generating the modified etch contour 1110 for the modified mean resist contour 1105. The size of the perturbation 1102 may be represented as E, and the perturbation shape may be a sharp delta peak at the point of interest F. The modified etch contour may then be considered as a mean etch contour plus perturbation at some points \vec{r}′ along the contour. The etch contour may be represented as:

$$EC ( \vec{r} ) + δ EC ( \vec{r} ′ ) = M [ RC ( \vec{r} ) + ε peak ( \vec{r} ) ] \qquad Eq . ( 9 )$$

The sensitivity, S, of a perturbation at the point \vec{r} may then be defined as a function of the modified resist contour, mean resist contour and the size of the deformation added to the resist contour. The sensitivity may be represented as follows: PG,

$$S ( \vec{r} , \vec{r} ′ ) = \frac{M [ R C ( \vec{r} ) + ε peak ( \vec{r} ) ] - M [ RC ( \vec{r} ) ]}{ε} \qquad Eq . ( 10 )$$

Note that for a fixed value \vec{r}, S(\vec{r}, \vec{r}′) is a vector with values for all contour points \vec{r}′ along the etch contour. For all values of F on the resist contour, the S(\vec{r}, \vec{r}′) is a matrix that depends on both the position F along the resist contour and the position \vec{r}′ along the etch contour. In some embodiments, a contour deformation at r in the resist contour yields a contour deformation at the same point \vec{r}′=\vec{r} in the etch contour and therefore, the matrix S(\vec{r}, \vec{r}′) may be considered to have a strong diagonal component. Therefore, the sensitivity variation, δS, may be represented as:

$$δ S ( \vec{r} , \vec{r} ′ ) = S ( \vec{r} , \vec{r} ′ ) - \qquad Eq . ( 11 )$$

Where [symbol] is the identity matrix, and δS(\vec{r}, \vec{r}′) is usually small in magnitude (e.g., δS(\vec{r}, \vec{r}′)«1 or δS(\vec{r}, \vec{r}′)<0.3).

Accordingly, based on Equations (6) and (11), the post-etch stochastic variation may be expressed as:

$${( γ ( \vec{r} ) {σ}_{SEPE - L} ( \vec{r} ) )}^{2} \approx {σ}_{SEPE - L} ( \vec{r} ) {( 1 + 2 Γ ( 1 + \frac{1}{2 α} ) ξ δ S ( \vec{r} , \vec{r} ) )}^{2} \qquad Eq . ( 12 )$$

Thus, the sensitivity may be represented as:

$$γ ( \vec{r} ) = 1 + 2 Γ ( 1 + \frac{1}{2 α} ) ξ δ S ( \vec{r} , \vec{r} ) \qquad Eq . ( 13 )$$

Embodiments of the present disclosure can be further described by the following clauses.
1. A non-transitory computer-readable medium having instructions that, when executed by a computer, cause the computer to execute a method for predicting post-etch stochastic variation in transferring a target layout onto a substrate using a lithographic apparatus, the method comprising:
   predicting a stochastic variation in transferring a target layout onto a substrate by executing a stochastic model configured to predict the stochastic variation in an etch process, wherein the stochastic model is configured to predict the stochastic variation based on stochastic etch bias and post-lithographic process stochastic variation; and
   determining a performance in transferring the target layout to the substrate based on the stochastic variation.
2. The computer-readable medium of clause 1, wherein the stochastic variation indicates a variation probability of a post-etch contour.
3. The computer-readable medium of clause 1, wherein the post-lithographic process stochastic variation indicates a variation of a contour associated with the target layout in a resist on the substrate after a lithographic process.
4. The computer-readable medium of clause 1, wherein predicting the stochastic variation includes: determining the stochastic etch bias using at least one of a concentration etch method, density map, or a smooth factor.
5. The computer-readable medium of clause 1, further including:
   obtaining substrate-level stochastic etch bias based on metrology data associated with a specified substrate; and
   calibrating a first stochastic model based on the substrate-level stochastic etch bias to determine parameters associated with the first stochastic model.
6. The computer-readable medium of clause 5, wherein the parameters include coefficients associated with at least one of plasma concentration-based method's term C_{T} and C_{R}, a pattern density map of sublayer, or a smooth factor.
7. The computer-readable medium of clause 5, wherein obtaining the substrate-level stochastic etch bias includes:
   obtaining, based on the metrology data, a first stochastic variation after a lithographic process of printing a pattern on the specified substrate;
   obtaining, based on the metrology data, a second stochastic variation after an etching process of etching the pattern on the specified substrate; and
   determining the substrate-level stochastic etch bias as a difference between the first stochastic variation and the second stochastic variation.
8. The computer-readable medium of clause 5 further comprising:
   inputting information associated with at least one of plasma concentration-based method's term C_{T} and C_{R}, a pattern density map of sublayer, or a smooth factor for a feature of the target layout to the first stochastic model; and
   obtaining the stochastic etch bias for the feature from the first stochastic model.
9. The computer-readable medium of clause 1, wherein the post-lithographic process stochastic variation is determined by executing a second stochastic model that is configured to predict the post-lithographic process stochastic variation of a contour associated with the target layout in a resist on the substrate.
10. The computer-readable medium of clause 9, wherein the second stochastic model is configured to predict the post-lithographic process stochastic variation based on at least one of optical sensitivity associated with the lithographic apparatus, photon two-dimensional distribution on the substrate, photon three-dimensional distribution on the substrate, or resist chemistry associated with a resist used in printing the target layout on the substrate.
11. The computer-readable medium of clause 1, wherein the stochastic model is configured to predict the stochastic variation as a combination of the stochastic etch bias and the post-lithographic process stochastic variation.
12. The computer-readable medium of clause 1 further comprising:
   obtaining a mean contour of a feature in the target layout by executing an etch model that is configured to predict the mean contour of the feature after the etch process is completed; and
   predicting a post-etch contour based on the mean contour and the stochastic variation.
13. The computer-readable medium of clause 12, wherein predicting the post-etch contour includes:
   determining a first post-etch contour at a first distance from the mean contour based on the stochastic variation; and
   determining a second post-etch contour at a second distance from the mean contour based on the stochastic variation.
14. The computer-readable medium of clause 1, wherein determining the performance in printing the target layout on the substrate includes:
   determining a performance of at least one of a lithographic process or an etch process in transferring the target layout to the substrate based on the stochastic variation.
15. The computer-readable medium of clause 1, wherein determining the performance in transferring the target layout includes:
   determining at least one of intra-layer defects or interlayer defects on the substrate based on the stochastic variation.
16. The computer-readable medium of clause 15, wherein determining the intra-layer defects includes:
   for a feature pair in the same layer of the target layout, wherein each feature of the feature pair includes multiple predicted post-etch contours, determining a failure probability that a distance between any of a plurality of contour pairs is less than a threshold distance, wherein a contour pair of the plurality of contour pairs includes a first post-etch contour of a first feature and a second post-etch contour of a second feature; and
   predicting a defect based on the failure probability satisfying a threshold probability.
17. The computer-readable medium of clause 15, wherein determining the interlayer defects includes:
   for a feature pair in consecutive layers of the target layout, wherein a first feature of the feature pair is in a first layer of the target layout and a second feature of the feature pair is in a second layer of the target layout, wherein each feature of the feature pair includes multiple predicted post-etch contours, determining a failure probability that a distance between any of a plurality of contour pairs is less than a threshold distance, wherein a contour pair of the plurality of contour pairs includes a first post-etch contour of the first feature and a second post-etch contour of the second feature; and
   predicting a defect based on the failure probability satisfying a threshold probability.
18. The computer-readable medium of clause 1 further comprising:
   configuring one or more of a mask or an illumination source of the lithographic apparatus based on the performance of a lithographic process.
19. The computer-readable medium of clause 18 further comprising:
   performing the lithographic process in the lithographic apparatus using the mask to print a target layout on the substrate.
20. The computer-readable medium of clause 1, wherein predicting the stochastic variation in transferring the target layout includes:
   obtaining a resist contour of a feature, the feature corresponding to one of multiple features in the target layout;
   obtaining an etch contour from the resist contour by executing an etch model, the etch contour representative of a contour of the feature after the etch process;
   determining a sensitivity of the etch contour to a stochastic variation in the resist contour; and
   determining the stochastic variation in the etch contour based on the stochastic variation in the resist contour and the sensitivity.
21. The computer-readable medium of clause 20, wherein determining the stochastic variation in the etch contour includes determining a product of the stochastic variation in the resist contour and the sensitivity.
22. The computer-readable medium of clause 21 further comprising:
   determining the stochastic variation in the etch contour as a function of a constant, which is indicative of a variation induced by an etch process.
23. The computer-readable medium of clause 20, wherein the sensitivity is a function of correlation length of a resist.
24. The computer-readable medium of clause 20, wherein determining the sensitivity includes executing an etch bias model to determine an etch bias based on multiple parameters.
25. The computer-readable medium of clause 24, wherein the parameters include at least one of plasma concentration-based method's term C_{T} and C_{R}, a pattern density map of sublayer, or a smooth factor, and coefficients associated with the parameters.
26. The computer-readable medium of clause 25, wherein the sensitivity is determined as a function of the coefficients.
27. The computer-readable medium of clause 20, wherein the sensitivity is determined as a function of one or more convolutions of the resist contour with a kernel.
28. The computer-readable medium of clause 20, wherein the sensitivity is determined as a function of truncation of a convolution of the resist contour.
29. The computer-readable medium of clause 20, wherein obtaining the resist contour includes executing a resist model that is configured to predict the resist contour of the feature from an aerial image.
30. The computer-readable medium of clause 20, wherein obtaining the resist contour further includes:
   determining the stochastic variation in the resist contour by executing a post-lithographic process stochastic variation model that is configured to predict the stochastic variation in the resist contour.
31. The computer-readable medium of clause 20, wherein the post-lithographic process stochastic variation model is configured to predict the stochastic variation in the resist contour based on at least one of optical sensitivity associated with a lithographic apparatus, photon two-dimensional distribution on the substrate, photon three-dimensional distribution on the substrate, or resist chemistry associated with a resist used in printing the target layout on the substrate.
32. The computer-readable medium of clause 20, wherein the stochastic variation in the resist contour indicates a variation of a contour associated with feature in a resist on the substrate after a lithographic process.
33. The computer-readable medium of clause 20, wherein the stochastic variation in the etch contour indicates a variation probability of a contour of the feature after an etch process.
34. The computer-readable medium of clause 20, wherein determining the sensitivity includes:
   determining the sensitivity based on a derivative of the etch model that is configured to predict the etch profile from the resist profile.
35. The computer-readable medium of clause 20, wherein determining the sensitivity includes:
   determining a derivative of the etch profile with respect to the resist profile.
36. The computer-readable medium of clause 35, wherein determining the derivative includes:
   adding a perturbation to the resist profile to generate a modified resist profile; and executing the etch model to generate a modified etch profile using the modified resist profile.
37. The computer-readable medium of clause 36 further comprising:
   determining the derivative based on the modified etch profile, the etch profile, and a size of the perturbation.
38. The computer-readable medium of clause 35, wherein determining the sensitivity includes: determining the sensitivity based on the derivative and a correlation length of a resist.
39. A non-transitory computer-readable medium having instructions that, when executed by a computer, cause the computer to execute a method for predicting post-etch stochastic variation in transferring a target layout to a substrate using a lithographic apparatus, the method comprising:
   obtaining post-lithographic process stochastic variation associated with printing a target layout on a substrate using a lithographic process;
   predicting stochastic etch bias that is indicative of a stochastic variation in an etch process of etching a pattern corresponding to the target layout on the substrate, wherein the stochastic etch bias is determined as a function of at least one of concentration etch method, a density map, or a smooth factor; and
   obtaining the stochastic variation based on the stochastic etch bias and the post-lithographic process stochastic variation.
40. The computer-readable medium of clause 39, wherein the stochastic variation indicates a variation probability of a post-etch contour.
41. The computer-readable medium of clause 39, wherein the post-lithographic process stochastic variation indicates a variation of a contour associated with the target layout in a resist on the substrate after the lithographic process.
42. The computer-readable medium of clause 39, wherein determining the stochastic etch bias includes:
   obtaining substrate-level stochastic etch bias based on metrology data associated with a specified substrate; and
   calibrating a first stochastic model based on the substrate-level stochastic etch bias to determine parameters associated with the first stochastic model.
43. The computer-readable medium of clause 42, wherein the parameters include coefficients associated with at least one of plasma concentration-based method's term C_{T} and C_{R}, a pattern density map of sublayer, or a smooth factor.
44. The computer-readable medium of clause 42, wherein obtaining the substrate-level stochastic etch bias includes:
   obtaining, based on the metrology data, a first stochastic variation after a lithographic process of printing a pattern on the specified substrate;
   obtaining, based on the metrology data, a second stochastic variation after an etching process of etching the pattern on the specified substrate; and
   determining the substrate-level stochastic etch bias as a difference between the first stochastic variation and the second stochastic variation.
45. The computer-readable medium of clause 42 further comprising:
   inputting information associated with at least one of plasma concentration-based method's term C_{T} and C_{R}, a pattern density map of sublayer, or a smooth factor for a feature of the target layout to the first stochastic model; and
   obtaining the stochastic etch bias for the feature from the first stochastic model.
46. The computer-readable medium of clause 42, wherein the post-lithographic process stochastic variation is determined by executing a second stochastic model that is configured to predict the post-lithographic process stochastic variation of a contour associated with the target layout in a resist on the substrate.
47. The computer-readable medium of clause 46, wherein the second stochastic model is configured to predict the post-lithographic process stochastic variation based on at least one of optical sensitivity associated with the lithographic apparatus, photon two-dimensional distribution on the substrate, photon three-dimensional distribution on the substrate, or resist chemistry associated with a resist used in printing the target layout on the substrate.
48. The computer-readable medium of clause 39 further comprising:
   obtaining a mean contour of a feature in the target layout by executing an etch model that is configured to predict the mean contour of the feature after the etch process is completed; and
   predicting a post-etch contour based on the mean contour and the stochastic variation.
49. The computer-readable medium of clause 48, wherein predicting the post-etch contour includes:
   determining a first post-etch contour at a first distance from the mean contour based on the stochastic variation; and
   determining a second post-etch contour at a second distance from the mean contour based on the stochastic variation.
50. The computer-readable medium of clause 39 further comprising:
   determining a performance of at least one of the lithographic process or the etch process in transferring the target layout to the substrate based on the stochastic variation.
51. The computer-readable medium of clause 50, wherein determining the performance in transferring the target layout includes:
   determining at least one of intra-layer defects or interlayer defects on the substrate based on the stochastic variation.
52. The computer-readable medium of clause 51, wherein determining the intra-layer defects includes:
   for a feature pair in the same layer of the target layout, wherein each feature of the feature pair includes multiple predicted post-etch contours, determining a failure probability that a distance between any of a plurality of contour pairs is less than a threshold distance, wherein a contour pair of the plurality of contour pairs includes a first post-etch contour of a first feature and a second post-etch contour of a second feature; and
   predicting a defect based on the failure probability satisfying a threshold probability.
53. The computer-readable medium of clause 51, wherein determining the interlayer defects includes:
   for a feature pair in consecutive layers of the target layout, wherein a first feature of the feature pair is in a first layer of the target layout and a second feature of the feature pair is in a second layer of the target layout, wherein each feature of the feature pair includes multiple predicted post-etch contours, determining a failure probability that a distance between any of a plurality of contour pairs is less than a threshold distance, wherein a contour pair of the plurality of contour pairs includes a first post-etch contour of the first feature and a second post-etch contour of the second feature; and
   predicting a defect based on the failure probability satisfying a threshold probability.
54. A method for predicting post-etch stochastic variation in transferring a target layout onto a substrate using a lithographic apparatus, the method comprising:
   predicting a stochastic variation in transferring a target layout onto a substrate by executing a stochastic model configured to predict the stochastic variation in an etch process, wherein the stochastic model is configured to predict the stochastic variation based on stochastic etch bias and post-lithographic process stochastic variation; and
   determining a performance in transferring the target layout to the substrate based on the stochastic variation.
55. An apparatus for predicting post-etch stochastic variation in transferring a target layout onto a substrate using a lithographic apparatus, the apparatus comprising:
   a memory storing a set of instructions; and
   a processor configured to execute the set of instructions to cause the apparatus to perform a method of:
   predicting a stochastic variation in transferring a target layout onto a substrate by executing a stochastic model configured to predict the stochastic variation in an etch process, wherein the stochastic model is configured to predict the stochastic variation based on stochastic etch bias and post-lithographic process stochastic variation; and
   determining a performance in transferring the target layout to the substrate based on the stochastic variation.
56. A non-transitory computer-readable medium having instructions that, when executed by a computer, cause the computer to execute a method for predicting post-etch stochastic variation in transferring a target layout onto a substrate using a lithographic apparatus, the method comprising:
   obtaining a resist profile of a feature, the feature corresponding to one of multiple features in a target layout to be transferred onto a substrate;
   obtaining an etch profile from the resist profile by executing an etch model, the etch profile representative of a contour of the feature after an etch process;
   determining a sensitivity of the etch profile to a stochastic variation in the resist profile; and
   determining a stochastic variation in the etch profile based on the stochastic variation in the resist profile and the sensitivity.
57. The computer-readable medium of clause 56, wherein determining the stochastic variation in the etch profile includes determining a product of the stochastic variation in the resist profile and the sensitivity.
58. The computer-readable medium of clause 57 further comprising:
   determining the stochastic variation in the etch profile as a function of a constant, which is indicative of a variation induced by an etch process.
59. The computer-readable medium of clause 56, wherein the sensitivity is a function of correlation length of a resist.
60. The computer-readable medium of clause 56, wherein determining the sensitivity includes executing an etch bias model to determine an etch bias based on multiple parameters.
61. The computer-readable medium of clause 60, wherein the parameters include at least one of plasma concentration-based method's term C_{T} and C_{R}, a pattern density map of sublayer, or a smooth factor, and coefficients associated with the parameters.
62. The computer-readable medium of clause 61, wherein the sensitivity is determined as a function of the coefficients.
63. The computer-readable medium of clause 56, wherein the sensitivity is determined as a function of one or more convolutions of the resist profile with a kernel.
64. The computer-readable medium of clause 56, wherein the sensitivity is determined as a function of truncation of a convolution of the resist profile.
65. The computer-readable medium of clause 56, wherein obtaining the resist profile includes executing a resist model that is configured to predict the resist profile of the feature from an aerial image.
66. The computer-readable medium of clause 56, wherein obtaining the resist profile further includes: determining the stochastic variation in the resist profile by executing a post-lithographic process stochastic variation model that is configured to predict the stochastic variation in the resist profile.
67. The computer-readable medium of clause 66, wherein the post-lithographic process stochastic variation model is configured to predict the stochastic variation in the resist profile based on at least one of optical sensitivity associated with a lithographic apparatus, photon two-dimensional distribution on the substrate, photon three-dimensional distribution on the substrate, or resist chemistry associated with a resist used in printing the target layout on the substrate.
68. The computer-readable medium of clause 56, wherein the stochastic variation in the resist profile indicates a variation of a contour associated with feature in a resist on the substrate after a lithographic process.
69. The computer-readable medium of clause 56, wherein the stochastic variation in the etch profile indicates a variation probability of a contour of the feature after an etch process.
70. The computer-readable medium of clause 56 further comprising:
   configuring one or more of a mask or an illumination source of a lithographic apparatus based on the stochastic variation of the etch profile.
71. The computer-readable medium of clause 56 further comprising:
   performing a lithographic process in the lithographic apparatus using the mask to print a target layout on the substrate.
72. The computer-readable medium of clause 56, wherein determining the sensitivity includes:
   determining the sensitivity based on a derivative of the etch model that is configured to predict the etch profile from the resist profile.
73. The computer-readable medium of clause 56, wherein determining the sensitivity includes:
   determining a derivative of the etch profile with respect to the resist profile.
74. The computer-readable medium of clause 73, wherein determining the derivative includes: adding a perturbation to the resist profile to generate a modified resist profile; and executing the etch model to generate a modified etch profile using the modified resist profile.
75. The computer-readable medium of clause 74 further comprising:
   determining the derivative based on the modified etch profile, the etch profile, and a size of the perturbation.
76. The computer-readable medium of clause 73, wherein determining the sensitivity includes: determining the sensitivity based on the derivative and a correlation length of a resist.
77. A method for predicting post-etch stochastic variation in transferring a target layout onto a substrate using a lithographic apparatus, the method comprising:
   obtaining a resist profile of a feature, the feature corresponding to one of multiple features in a target layout to be transferred onto a substrate;
   obtaining an etch profile from the resist profile by executing an etch model, the etch profile representative of a contour of the feature after an etch process;
   determining a sensitivity of the etch profile to a stochastic variation in the resist profile; and determining a stochastic variation in the etch profile based on the stochastic variation in the resist profile and the sensitivity.
78. An apparatus for predicting post-etch stochastic variation in transferring a target layout onto a substrate using a lithographic apparatus, the apparatus comprising:
   a memory storing a set of instructions; and
   a processor configured to execute the set of instructions to cause the apparatus to perform a method of:
   obtaining a resist profile of a feature, the feature corresponding to one of multiple features in a target layout to be transferred onto a substrate;
   obtaining an etch profile from the resist profile by executing an etch model, the etch profile representative of a contour of the feature after an etch process;
   determining a sensitivity of the etch profile to a stochastic variation in the resist profile; and
   determining a stochastic variation in the etch profile based on the stochastic variation in the resist profile and the sensitivity.

1. A non-transitory computer-readable medium having instructions that, when executed by a computer system, are configured to cause the computer system to at least:
predict a stochastic variation in transferring a target layout onto a substrate by executing a stochastic model configured to predict the stochastic variation in an etch process, wherein the stochastic model is configured to predict the stochastic variation based on stochastic etch bias and post-lithographic process stochastic variation; and
determine a performance in transferring the target layout to the substrate based on the stochastic variation.

2. The computer-readable medium of claim 1, wherein the stochastic variation indicates a variation probability of a post-etch contour.

3. The computer-readable medium of claim 1, wherein the post-lithographic process stochastic variation indicates a variation of a contour associated with the target layout in a resist on the substrate after a lithographic process.

4. The computer-readable medium of claim 1, wherein the instructions are further configured to cause the computer system to determine the stochastic etch bias using at least one selected from: a concentration etch method, density map, or a smooth factor.

5. The computer-readable medium of claim 1, wherein the instructions are further configured to cause the computer system to:
obtain substrate-level stochastic etch bias based on metrology data associated with a specified substrate; and
calibrate a first stochastic model based on the substrate-level stochastic etch bias to determine parameters associated with the first stochastic model.

6. The computer-readable medium of claim 5, wherein the parameters include coefficients associated with at least one selected from: plasma concentration-based method's terms, a pattern density map of sublayer, or a smooth factor.

7. The computer-readable medium of claim 5, wherein the instructions configured to cause the computer system to obtain the substrate-level stochastic etch bias are further configured to cause the computer system to:
obtain, based on the metrology data, a first stochastic variation after a lithographic process of printing a pattern on the specified substrate;
obtain, based on the metrology data, a second stochastic variation after an etching process of etching the pattern on the specified substrate; and
determine the substrate-level stochastic etch bias as a difference between the first stochastic variation and the second stochastic variation.

8. The computer-readable medium of claim 1, wherein the post-lithographic process stochastic variation is determined by execution of a second stochastic model that is configured to predict the post-lithographic process stochastic variation of a contour associated with the target layout in a resist on the substrate.

9. The computer-readable medium of claim 8, wherein the second stochastic model is configured to predict the post-lithographic process stochastic variation based on at least one selected from: optical sensitivity associated with the lithographic apparatus, photon two-dimensional distribution on the substrate, photon three-dimensional distribution on the substrate, or resist chemistry associated with a resist used in printing the target layout on the substrate.

10. The computer-readable medium of claim 1, wherein the stochastic model is configured to predict the stochastic variation as a combination of the stochastic etch bias and the post-lithographic process stochastic variation.

11. The computer-readable medium of claim 1, wherein the instructions are further configured to cause the computer system to:
obtain a mean contour of a feature in the target layout by execution of an etch model that is configured to predict the mean contour of the feature after the etch process is completed; and
predict a post-etch contour based on the mean contour and the stochastic variation, wherein the prediction of the post-etch contour includes:
determination of a first post-etch contour at a first distance from the mean contour based on the stochastic variation; and
determination of a second post-etch contour at a second distance from the mean contour based on the stochastic variation.

12. The computer-readable medium of claim 1, wherein the instructions configured to cause the computer system to determine the performance in transferring the target layout are further configured to cause the computer system to determine a defect on the substrate based on the stochastic variation.

13. The computer-readable medium of claim 12, wherein the instructions configured to cause the computer system to determine the defect are further configured to cause the computer system to:
for a feature pair in the same layer of the target layout, wherein each feature of the feature pair includes multiple predicted post-etch contours, determine a failure probability that a distance between any of a plurality of contour pairs is less than a threshold distance, wherein a contour pair of the plurality of contour pairs includes a first post-etch contour of a first feature and a second post-etch contour of a second feature; and
predict the defect based on the failure probability satisfying a threshold probability.

14. The computer-readable medium of claim 12, wherein the instructions configured to cause the computer system to determine the defect are further configured to cause the computer system to:
for a feature pair in consecutive layers of the target layout, wherein a first feature of the feature pair is in a first layer of the target layout and a second feature of the feature pair is in a second layer of the target layout, wherein each feature of the feature pair includes multiple predicted post-etch contours, determine a failure probability that a distance between any of a plurality of contour pairs is less than a threshold distance, wherein a contour pair of the plurality of contour pairs includes a first post-etch contour of the first feature and a second post-etch contour of the second feature; and
predict the defect based on the failure probability satisfying a threshold probability.

15. The computer-readable medium of claim 1, wherein the instructions are further configured to cause the computer system to:
configure a mask or an illumination of the lithographic apparatus, based on the performance of a lithographic process; or
cause performance of the lithographic process in the lithographic apparatus using the mask to print a target layout on the substrate.

16. A non-transitory computer-readable medium having instructions that, when executed by a computer system, are configured to cause the computer system to at least:
obtain post-lithographic process stochastic variation associated with printing a target layout on a substrate using a lithographic process;
predict stochastic etch bias that is indicative of a stochastic variation in an etch process of etching a pattern corresponding to the target layout on the substrate, wherein the stochastic etch bias is determined as a function of at least one selected from: concentration etch method, a density map, or a smooth factor; and
obtain the stochastic variation based on the stochastic etch bias and the post-lithographic process stochastic variation.

17. The computer-readable medium of claim 16, wherein the stochastic variation indicates a variation probability of a post-etch contour.

18. The computer-readable medium of claim 16, wherein the post-lithographic process stochastic variation indicates a variation of a contour associated with the target layout in a resist on the substrate after the lithographic process.

19. The computer-readable medium of claim 16, wherein the instructions are further configured to cause the computer system to:
obtain substrate-level stochastic etch bias based on metrology data associated with a specified substrate; and
calibrate a stochastic model based on the substrate-level stochastic etch bias to determine parameters associated with the stochastic model.

20. The computer-readable medium of claim 16, wherein the instructions are further configured to cause the computer system to:
obtain a mean contour of a feature in the target layout by execution of an etch model that is configured to predict the mean contour of the feature after the etch process is completed; and
predict a post-etch contour based on the mean contour and the stochastic variation.
